(19) United States
(12) Patent Application Publication
(10) Pub. No.: US 2003/0129839 A1
(43) Pub. Date: Jul. 10, 2003

(54) Method of forming a liner in shallow trench isolation

(76) Inventors: Shyh-Dar Lee, Hsinchu Hsien (TW); Fung-Hsu Cheng, Taoyuan (TW)

Correspondence Address: BIRCH STEWART KOLASCH & BIRCH, PO BOX 747, FALLS CHURCH, VA, 22040-0747, US

(21) Appl. No.: 10/035,175

(22) Filed: Jan. 4, 2002

(51) Int. Cl. H01L 21/311

(52) U.S. Cl. 438/694

(57) ABSTRACT

A method of forming a shallow trench isolation has the steps of: forming a plurality of trenches in a semiconductor substrate; forming an oxide liner on the bottom and sidewall of each trench; and thermal annealing in a nitrogen-containing atmosphere to dope nitrogen elements in the oxide liner. Thus, a nitrogen-rich layer is formed at the interface between the oxide liner and the semiconductor substrate.

### BACKGROUND OF THE INVENTION

1. Field of the Invention

The present invention relates to shallow trench isolation technology and, more particularly, to a method of forming an oxide liner with nitrogen elements in the shallow trench isolation.

2. Description of the Related Art

Escalating demands for high density and performance associated with ultra large scale integration require semiconductor devices with design features of 0.18 microns and under, e.g. 0.15 μm and 0.13 μm, increased transistor and circuit speeds, high reliability, and increased manufacturing throughput. The reduction of design features challenges the limitations of conventional semiconductor technology for isolating active regions. One type of isolation is known as local oxidation of silicon (LOCOS) that disadvantageously results in bird's beak phenomenon, and the other type of isolation is shallow trench isolation (STI) that provides a very good device-to-device isolation and reduces bird's beak phenomenon.

FIGS. 1A to 1F are sectional diagrams showing a conventional STI process. As shown in FIG. 1A, a silicon substrate 10 is provided with a pad oxide layer 12, a pad nitride layer 14, a SiON layer 16 and a photo-resist layer 18. Then, as shown in FIG. 1B, using photolithography, the photo-resist layer 18 is patterned to form a plurality of openings 20 that have a width substantially corresponding to the width of the subsequently formed trench. Next, as shown in FIG. 1C, using anisotropic dry etching with the patterned photo-resist layer 18 as a mask, a plurality of trenches 22 of 2000-8000 Å depth are formed in the silicon substrate 10. Thereafter, as shown in FIG. 1D, the patterned photo-resist layer 18 is removed.

As shown in FIG. 1E, using thermal oxidation, an oxide liner 24 is grown on the bottom and sidewall of the trench 22 to release the remaining stress existed after dry etching. Next, as shown in FIG. 1F, an insulating layer 26 is deposited on the entire surface of the silicon substrate 10 to fill the trenches 22, and then chemical mechanical polishing (CMP) is used to planarize the insulating layer 26 until reaching the top of the pad nitride layer 14. Finally, the pad nitride layer 14 is removed, thus the insulating layer 26 remaining in the trench 22 serve as a STI region.

However, after dry etching to form the trenches 22, stress is disadvantageously induced at the sidewall of the trench 22. This remaining stress causes current leakage when the device works at a high power, and thus reduces the lifetime of the device. In order to release the remaining stress, as shown in FIG. 2, a silicon nitride liner 25 is deposited on the oxide liner 24. Nevertheless, after the subsequent CMP, the silicon nitride liner 25 is easily peeled at the angled region A. This further results in a particle issue. Moreover, the extra step of depositing the silicon nitride liner 25 has disadvantages of high cost, complex process, difficult control and reduced cycle time.

### SUMMARY OF THE INVENTION

The present invention is a method of forming a liner doping with nitrogen elements in the shallow trench isolation to solve the above-mentioned problems.

The method of forming a shallow trench isolation features of nitrogen-doping oxide liner has steps of: forming a plurality of trenches in the semiconductor substrate; forming an oxide liner on the bottom and sidewall of each trench; and thermal annealing the oxide liner in a nitrogen-containing atmosphere. Thus, a nitrogen-rich layer is formed at the interface between the oxide liner and the semiconductor substrate.

Accordingly, it is a principle object of the invention to provide an oxide liner doping with nitrogen elements in the trench.

Yet another object of the invention is to provide a nitrogen-rich layer at the interface between the oxide liner and the silicon substrate.

It is a further object of the invention to release the remaining stress at the sidewall of the trench caused by dry etch

Still another object of the invention is to achieve low cost and ease of process.

Another object of the invention is to reduce current leakage.

These and other objects of the present invention will become readily apparent upon further review of the following specification and drawings.

### BRIEF DESCRIPTION OF THE DRAWINGS

FIGS. 1A to 1F are sectional diagrams showing a conventional STI process.

FIG. 2 is a sectional diagram showing a silicon nitride liner on an oxide liner according to the prior art.

FIGS. 3A to 3G are sectional diagrams showing a novel STI process according to the present invention.

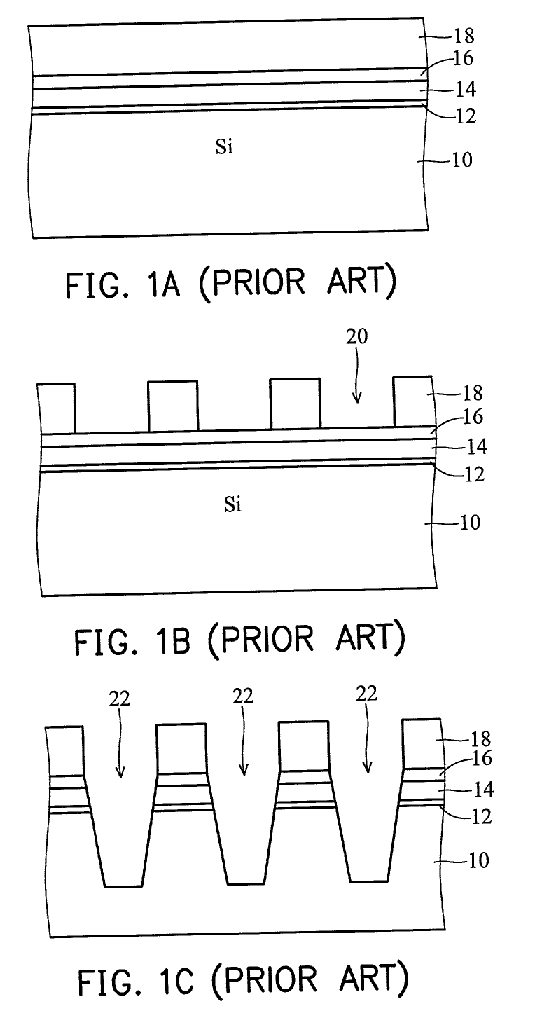

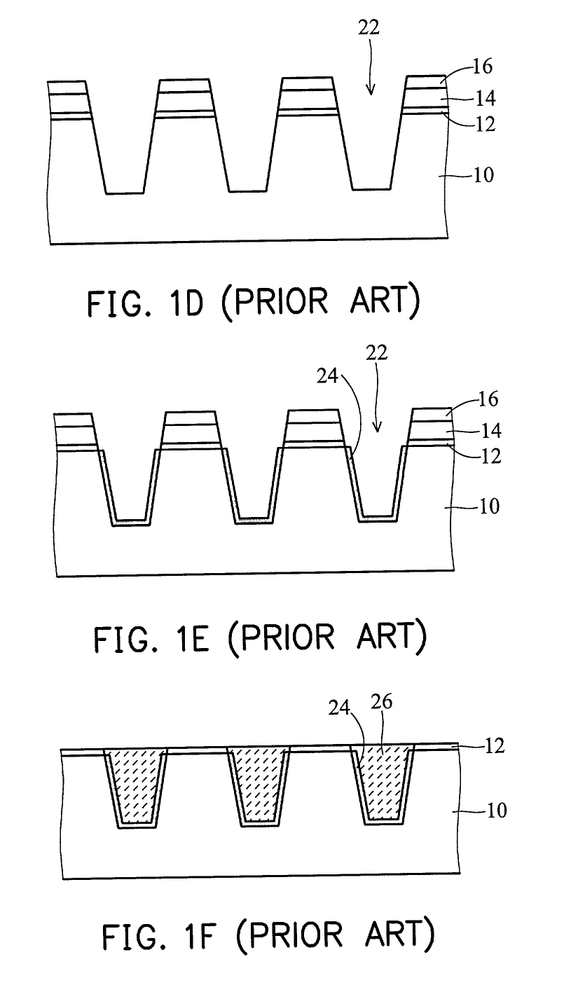

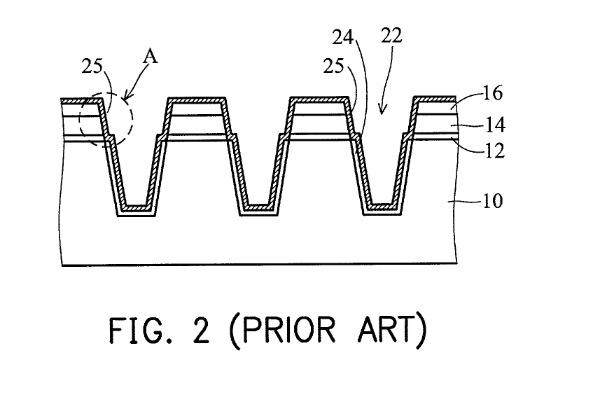

Similar reference characters denote corresponding features consistently throughout the attached drawings.

### DETAILED DESCRIPTION OF THE PREFERRED EMBODIMENTS

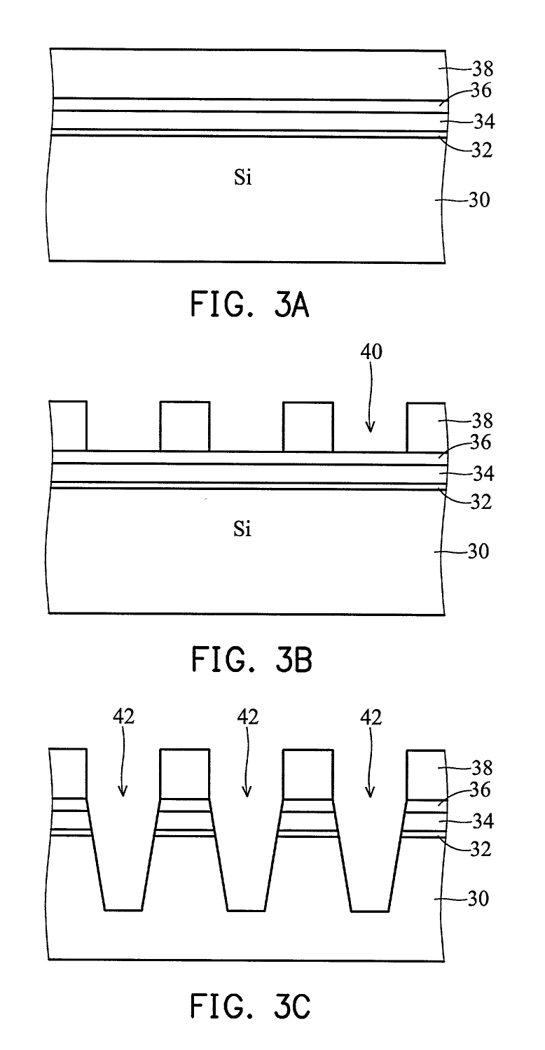

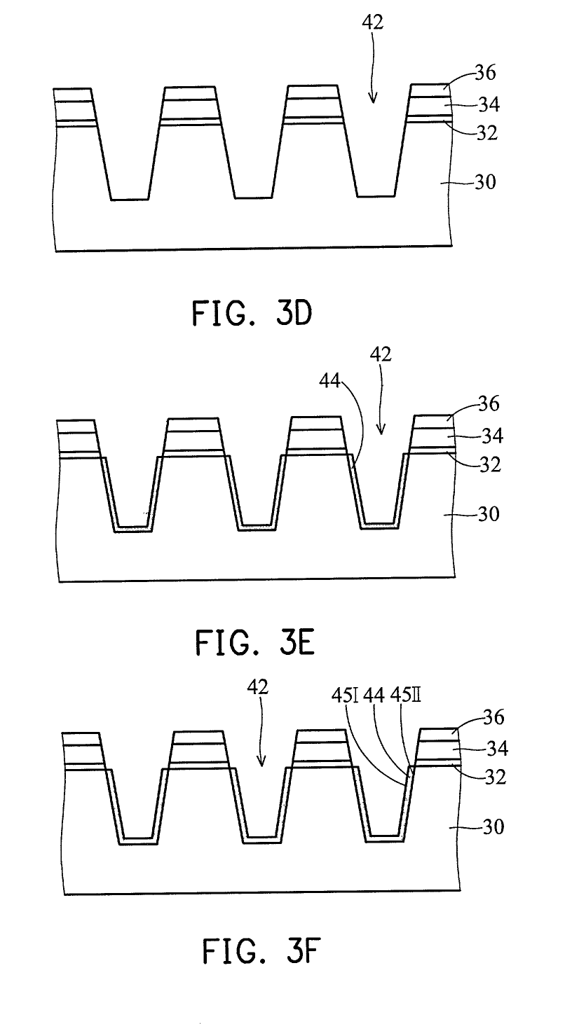

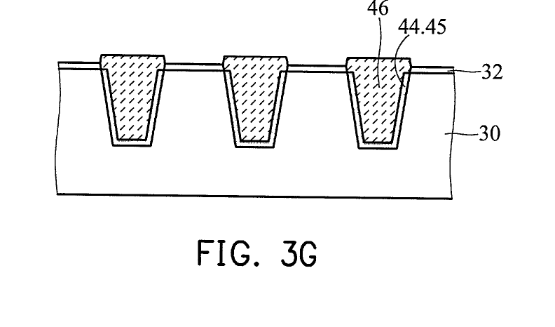

FIGS. 3A to 3G are sectional diagrams showing a novel STI process according to the present invention. As shown in FIG. 3A, a silicon substrate 30 is provided with a pad oxide layer 32, a pad nitride layer 34, a SiON layer 36 and a photo-resist layer 38. Then, as shown in FIG. 3B, using photolithography, the photo-resist layer 38 is patterned to form a plurality of openings 40 that have a width substantially corresponding to the width of the subsequently formed trench. Next, as shown in FIG. 3C, using anisotropic dry etching with the patterned photo-resist layer 38 as a mask, a plurality of trenches 42 of 2000-8000 Å depth is formed in the silicon substrate 30. Thereafter, as shown in FIG. 3D, the patterned photo-resist layer 38 is removed.

As shown in FIG. 3E, using thermal oxidation, an oxide liner 44 is grown on the bottom and sidewall of the trench 42 to release the remaining stress existed after dryetching. Next, as shown in FIG. 3F, using thermal annealing in a nitrogen-containing atmosphere, nitrogen elements are doped in the oxide liner 44 to serve as a first nitrogen-rich layer 45I on the oxide liner 44. Also, in accordance with the experimental results, it is found that the nitrogen elements existing at the interface between the oxide liner 44 and the silicon substrate 30 serve as a second nitrogen-rich layer 45II. Preferably, the nitrogen-containing atmosphere consisting of N₂, NH₃, N₂O, NOx or any nitrogen-containing compound, and the thermal annealing is performed at 650-850° C., 100-250 mtorr, for 1-30 minutes.

During thermal annealing in a nitrogen-containing atmosphere, nitrogen elements can react with oxygen elements in silicon dioxide. Since Si—N bonds are more flexible than the Si—O bonds, the dangling bond Si—N can release the remaining stress at the sidewall of the trench 42 caused by dry etching. That is, the stress from Si—N bonds compensates the stress from Si—O bonds.

Thereafter, as shown in FIG. 3G, using LPCVD, HDPCVD or any other well-known deposition, an insulating layer 46 is deposited on the entire surface of the silicon substrate 30 to fill the trenches 42. Then, CMP is used to planarize the insulating layer 46 until reaching the top of the pad nitride layer 34. Finally, the pad nitride layer 34 is removed, thus the insulating layer 46 remaining in the trench 42 serve as a STI region.

Compared with the prior method of forming the STI region, the prevent invention provides the thermal annealing in nitrogen-containing atmosphere to form the second nitrogen-rich layer 45II at the interface between the oxide liner 44 and the silicon substrate 30. Thus, nitrogen elements can react with oxygen elements in silicon dioxide to provide the dangling bond to release the remaining stress at the sidewall of the trench 42 caused by dry etch. This contributes advantages of low cost, easy process, and reducing current leakage issue.

It is to be understood that the present invention is not limited to the embodiments described above, but encompasses any and all embodiments within the scope of the following claims.

What is claimed is:

1. A method of forming a shallow trench isolation, comprising steps of:
forming a plurality of trenches in a semiconductor substrate;
forming an oxide liner on the bottom and sidewall of each trench; and
thermal annealing in a nitrogen-containing atmosphere to dope nitrogen elements in the oxide liner, wherein a nitrogen-rich layer is formed at the interface between the oxide liner and the semiconductor substrate.

2. The method according to claim 1, wherein the nitrogen-containing atmosphere comprises N₂, NH₃, N₂O, nitric oxide or any nitrogen-containing compound.

3. The method according to claim 1, wherein the thermal annealing is performed at 650˜850° C., 100˜250 mtorr, for 1-30 minutes.

4. The method according to claim 1, wherein the oxide liner is formed by thermal oxidation.

5. The method according to claim 1, wherein the trenches are formed by anisotropical dry etch.

6. The method according to claim 1, further comprising steps of:
depositing an insulating layer on the entire surface of the semiconductor substrate to fill the trenches; and
using chemical mechanical polishing (CMP) to planarize the insulating layer to reach the top of the semiconductor substrate.
